(19) United States
(12) Patent Application Publication
(10) Pub. No.: US 2006/0063680 A1
(43) Pub. Date: Mar. 23, 2006

(54) System and method for joining superconductivity tape

(75) Inventors: Alex Ignatiev, Houston, TX (US); Alexander A. Molodyk, Houston, TX (US); Louis D. Castellani, Houston, TX (US)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Metal Oxide Technologies, Inc., Houston, TX (US)

(21) Appl. No.: 11/039,711

(22) Filed: Jan. 19, 2005

Related U.S. Application Data
(63) Continuation-in-part of application No. 10/206,123, filed on Jul. 26, 2002.
(60) Provisional application No. 60/538,850, filed on Jan. 23, 2004.
(60) Provisional application No. 60/539,310, filed on Jan. 26, 2004.

(51) Int. Cl. H01L 39/22

(52) U.S. Cl. 505/329

(57) ABSTRACT

According to an embodiment, a portable system for joining two superconductor pieces comprises a support arranged for holding the two superconductor pieces adjacent to each other in a reaction area, a distribution head positioned to deposit at least one material onto the reaction area used in joining the two superconductor pieces, an ion gun positioned to bombard the reaction area with ions, a gas port arranged for providing at least one gas to the system, and a vacuum port arranged for establishing a desired atmospheric pressure in the system.

### CROSS-REFERENCE TO RELATED APPLICATIONS

This application claims priority to U.S. Provisional Patent Application No. 60/538,850, filed Jan. 23, 2004 and Unites States Provisional Patent Application No. 60/539,310, filed Jan. 26, 2004, the disclosures of which are hereby incorporated herein by reference. This application is related to co-pending and commonly assigned U.S. patent application Ser. No. 10/206,123, entitled “METHOD AND APPARATUS FOR FORMING SUPERCONDUCTOR MATERIAL ON A TAPE SUBSTRATE,” filed Jul. 26, 2002, to co-pending and commonly-assigned U.S. patent application Ser. No. 10/206,900, entitled “SUPERCONDUCTOR MATERIAL ON A TAPE SUBSTRATE,” filed Jul. 26, 2002, and concurrently filed and commonly assigned U.S. patent application Ser. No. 10/206,783, entitled “METHOD AND APPARATUS FOR FORMING A THIN FILM ON A TAPE SUBSTRATE,” filed Jul. 26, 2002, to U.S. patent application Ser. No. ______ [attorney docket no. 5837-P001CP1-10311280] filed concurrently herewith and entitled “METHOD AND APPARATUS FOR FORMING SUPERCONDUCTOR MATERIAL ON A TAPE SUBSTRATE,” to U.S. patent application Ser. No. ______ [attorney docket no. 5837-P004US10311281] filed concurrently herewith and entitled “SYSTEM AND METHOD FOR PROVIDING PRECURSORS,” and to U.S. patent application Ser. No. ______ [attorney docket no. 5837-P006US10311283] filed concurrently herewith and entitled “SYSTEM AND METHOD FOR QUALITY TESTING OF SUPERCONDUCTIVITY TAPE,” the disclosures of which are hereby incorporated herein by reference.

### TECHNICAL FIELD

This application relates in general to superconductor materials, and in specific to a system and method for joining superconductivity tape.

### BACKGROUND OF THE INVENTION

Electrical resistance in metals arises because electrons that are propagating through the solid are scattered because of deviations from perfect translational symmetry. These deviations are produced either by impurities or the phonon lattice vibrations. The impurities form the temperature independent contribution to the resistance, and the vibrations form the temperature dependent contribution.

Electrical resistance, in some applications, is very undesirable. For example, in electrical power transmission, electrical resistance causes power dissipation, i.e. loss. The power dissipation grows in proportion to the square of the current, namely P=I²R in normal wires. Thus, wires carrying large currents dissipate large amounts of energy. Moreover, the longer the wire used in either larger transformers, bigger motors or larger transmission distances, the more dissipation, since the resistance in a wire is proportional to its length. Thus, as wire lengths increase more energy is lost in the wires, even with a relatively small currents. Consequently, electric power plants produce more energy than that which is used by consumers, since a portion of the energy is lost due to wire resistance.

In a superconductor that is cooled below its transition temperature T_{C}, there is no resistance because the scattering mechanisms are unable to impede the motion of the current carriers. The current is carried, in most known classes of superconductor materials, by pairs of electrons known as Cooper pairs. The mechanism by which two negatively charged electrons are bound together is described by the BCS (Bardeen Cooper Schrieffer) theory. In the superconducting state, i.e. below T_{C}, the binding energy of a pair of electrons causes the opening of a gap in the energy spectrum at E_{f}, which is the Fermi energy or the highest occupied level in a solid. This separates the pair states from the “normal” single electron states. The size of a Cooper pair is given by the coherence length which is typically 1000 Å, although it can be as small as 30 Å in the copper oxides. The space occupied by one pair contains many other pairs, which forms a complex interdependence of the occupancy of the pair states. Thus, there is insufficient thermal energy to scatter the pairs, as reversing the direction of travel of one electron in the pair requires the destruction of the pair and many other pairs due to the complex interdependence. Consequently, the pairs carry current unimpeded. For further information on superconductor theory please see “Introduction to Superconductivity,” by M. Tinkham, McGraw-Hill, New York, 1975.)

Many different materials can become superconductors when their temperature is cooled below T_{C}. For example, some classical type I superconductors (along with their respective T_{C}'s in degrees Kelvin (K)) are carbon 15 K, lead 7.2 K, lanthanum 4.9 K, tantalum 4.47 K, and mercury 4.47 K. Some type II superconductors, which are part of the new class of high temperature superconductors (along with their respective T_{C}'s in degrees K), are Hg_{0.8}Tl_{0.2}Ba₂Ca₂Cu₃O_{8.33} 138 K, Bi₂Sr₂Ca₂Cu₃O₁₀ 118 k, and YBa₂Cu₃O₇₋ₓ 93 K. The last superconductor is also well known as YBCO superconductor, for its components, namely Yttrium, Barium, Copper, and Oxygen, and is regarded as the highest performance and highest stability high temperature superconductor, especially for electric power applications. YBCO has a Perovskite structure. This structure has a complex layering of the atoms in the metal oxide structure. FIG. 1 depicts the structure for YBa₂Cu₃O₇, that include Yttrium atoms 101, Barium atoms 102, Copper atoms 103, and Oxygen atoms 104. For further information on oxide superconductors please see “Oxide Superconductors”, Robert J. Cava, J. Am. Ceram. Soc., volume 83, number 1, pages 5-28, 2000.

A problem with YBCO superconductors specifically, and the oxide superconductors in general, is that they are hard to manufacture because of their oxide properties, and are challenging to produce in superconducting form because of their complex atomic structures. The smallest defect in the structure, e.g. a disordering of atomic structure or a change in chemical composition, can ruin or significantly degrade their superconducting properties. Defects may arise from many sources, e.g. impurities, wrong material concentration, wrong material phase, wrong processing temperature, poor atomic structure, and improper delivery of materials to the substrate, among others.

Thin film YBCO superconductors can be fabricated in many ways including pulsed laser deposition, sputtering, metal organic deposition, physical vapor deposition, and chemical vapor deposition. Two typical ways for the deposition of thin film YBCO superconductors are described here as example. In the first way, the YBCO is formed on a wafer substrate in a reaction chamber 200, as shown in FIG. 2 by metal organic chemical vapor deposition (MOCVD). This manner of fabrication is similar to that of semiconductor devices. The wafer substrate is placed on holder 201. The substrate is heated by heater 202. The wafer substrate is also rotated which allows for more uniform deposition on the substrate wafer, as well as more even heating of the substrate. Material, in the form of a gas, is delivered to the substrate by shower head 203, via inlet 204. The shower head 203 provides a laminar flow of the material onto the substrate wafer. The material collects on the heated wafer substrate to grow the superconductor. Excess material is removed from the chamber 200 via exhaust port 208, which is coupled to a pump. To prevent undesired deposition of material onto the walls of the chamber 200, coolant flows through jackets 205 in the walls. To prevent material build up inside the shower head 203, coolant flows through coils 206 in the shower head. The flanges port 207 allows access to the inside of the chamber 200 for insertion and removal of the film/substrate sample. Processing of the film may be monitored through optical port 209.

In the second way, depicted in FIG. 3, YBCO is formed by pulsed laser deposition on a substrate, including the possibility of using a continuous metal tape substrate 301. The tape substrate 301 is supported by two rollers 302, 303 inside of a reaction chamber 300. Roller 302 includes a heater 304, which heats the tape 301 up to a temperature that allows YBCO growth. The material 305 is vaporized in a plume from a YBCO target by irradiation of the target by typically an excimer laser 306. The vapor in the plume then forms the YBCO superconductor film on the substrate 301. The rollers 302, 303 allow for continuous motion of the tape past the laser target thus allowing for continuous coating of the YBCO material onto the tape. Note that the laser 306 is external to the chamber 300 and the beam from the laser 306 enters the chamber 300 via optical port 307. The resulting tape is then cut, and forms a tape or ribbon that has a layer of YBCO superconductive material.

Neither of the above described methods for forming thin film high temperature superconductors can produce a long length tape or ribbon of YBCO which can be used to replace copper (or other metal) wires in electric power applications. The first way only allows for the production of small pieces of superconductor material on the wafer, e.g. a batch process. The second way can only be used to make tape that is a few feet in length and uses multiple passes to generate a superconducting film of several microns thickness. The second way has a practical limitation of about 5 feet. Larger pieces of tape would require a larger heating chamber. A larger heating roller will also be needed. The tape will cool down after leaving roller 302, and thus will need more time to heat back up to the required temperature. Heating on one side of the chamber, with a cool down on the other side of the chamber may also induce thermal cracks into the YBCO layer and other layers formed on the metal substrate. The smaller pieces of tape produced by the second method may be spliced together to form a long length tape, but while the pieces may be superconducting, splice technology is not yet at the point of yielding high quality high temperature superconductor splices. Consequently, current arrangements for forming superconductors cannot form a long, continuous tape of superconductor material.

### BRIEF SUMMARY OF THE INVENTION

The present invention is directed to a system and method which allows for the splicing of coated conductor superconducting wire or tales. The coated conductor wire is typically comprised of a metal foil substrate which gives the strength and ductility to the wire, a buffer layer or layers which separate the superconducting layer from the substrate and prevent interdiffusion of species that could reduce the superconducting properties of the wire, and the superconducting layer deposited on top of the buffer layer(s). Splicing or joining of such a wire geometry may include structural joining of the metal foil substrate, fill-in of the metal foil substrates over the joint region, fill-in of the buffer layer(s) onto the splice region, and/or overlay of the superconducting layer over the joint with electrical/superconducting connectivity to both sides of the splice. In addition, the atomic order of the substrate, buffer layer(s) and the superconducting layer should be maintained throughout the splice region to make an effective superconducting joint. The present invention uses a portable joiner for joining two superconductor pieces. The joiner includes a support for holding the two superconductor pieces adjacent to each other. The substrate of the first piece is then welded to the substrate of the second piece. A patch made of substrate material may be provided at the weld point of the two pieces to provide more support for the mechanical connection. The patch would be welded to the substrate of both pieces.

The joiner includes an ion gun that is positioned to bombard the welded area with ions to clean the area and prepare the welded area to receive deposition materials. The joiner also includes a distribution head or shower head that is positioned to deposit various materials onto the welded region. These materials may include substrate material, buffer material, superconductor material, a protective layer material (e.g. silver). The joiner further includes a gas port for providing the various gases used in joining the pieces. The joiner further includes a vacuum port for establishing a desired atmospheric pressure in the joiner, and hermetic seals at either end to allow for control of the atmosphere inside the joiner.

After the mechanical connection of the two pieces, the joiner would form the electrical connection of the two pieces by depositing various layers. For example, the joiner may first deposit a layer of substrate material onto the welded area. The joiner may then deposit a layer of buffer material onto the deposited layer of substrate material. The joiner may then deposit a layer of superconductor material onto the buffer material. The deposited layer of superconductor material adjoins a superconductor layer of the first piece and adjoins a superconductor layer of the second piece, completing the electrical connection of the two pieces. The joiner may then deposit a layer of protective materials (e.g. silver) onto the deposited superconductor layer.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 depicts a known atomic structure for a YBCO superconductor;

FIG. 2 depicts a first prior art arrangement for producing a YBCO superconductor;

FIG. 3 depicts a second prior art arrangement for producing a YBCO superconductor;

FIG. 4 depicts exemplary portable joining system according to various embodiments of the invention;

FIGS. 5A-5G depict an exemplary joining of two superconductor pieces using the system of FIG. 4;

FIG. 6 depicts exemplary joined superconductor pieces according to FIGS. 5A-5F; and

FIG. 7 depicts an exemplary superconductor piece after operation of the system of FIG. 4 in FIG. 5C.

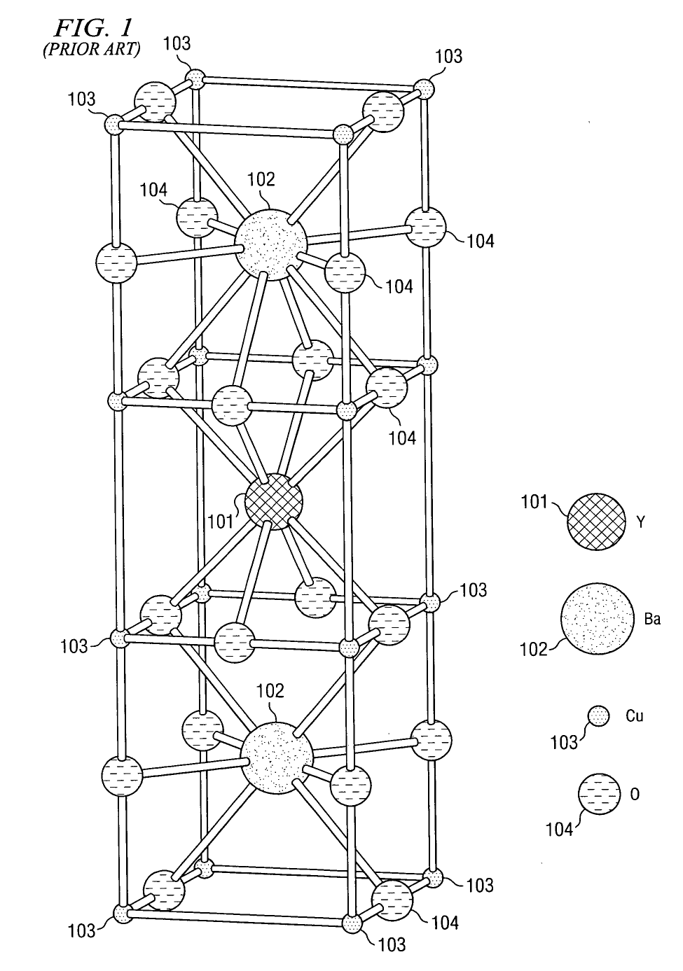

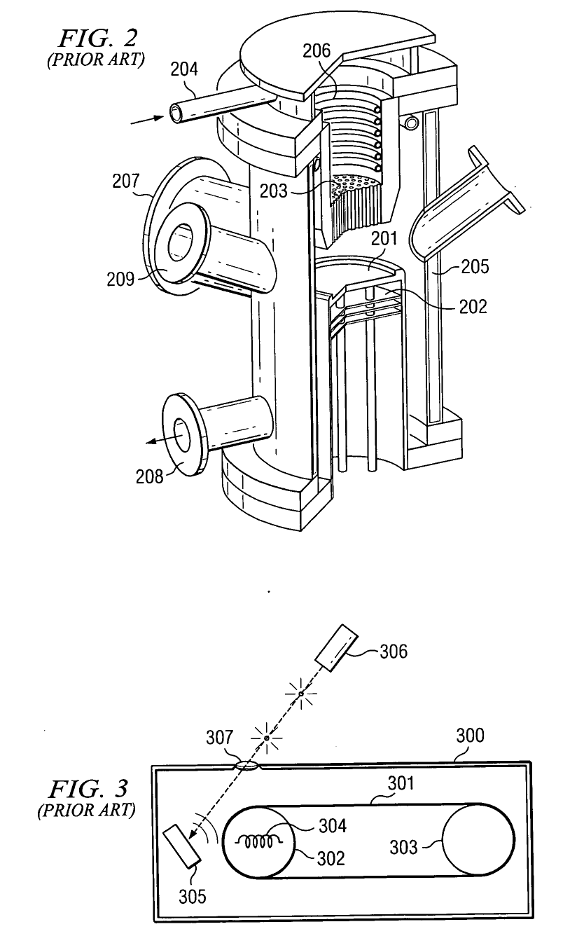

### DETAILED DESCRIPTION OF THE INVENTION

Various embodiments of the invention are manifested in a portable joiner. The portable joiner is used to join two pieces of superconductor (SC) material and form a single piece of material that retains the superconductive properties of the two pieces. The joiner joins the two pieces both mechanically and electrically. For example, two pieces of SC tape, each of which may be very long in length (e.g. 1000 meters) may be connected by the joiner. Since the joiner is portable, the two pieces that are to be joined may be in the field, and away from the production facility.

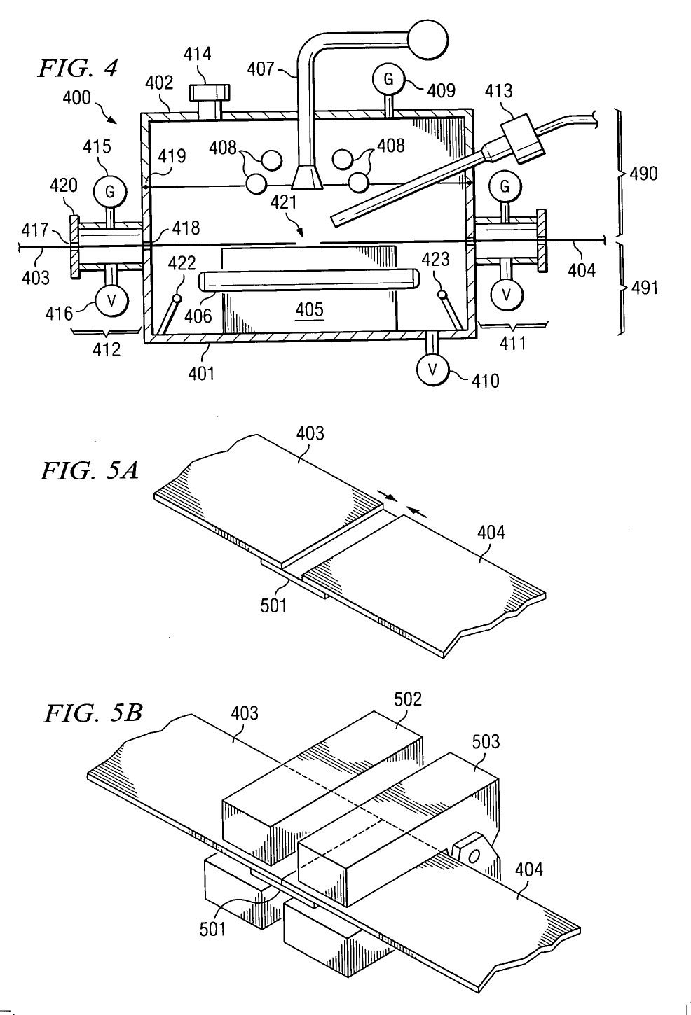

FIG. 4 depicts portable joiner 400 according to various embodiments of the invention. The joiner 400 that connects two superconductor pieces, 403, 404 to form a longer piece of high temperature superconducting (HTS) material. Joiner 400 operates to deposit a layer of SC material that connects the superconductor layers of the two pieces, such that the HTS material is atomically ordered with large, well-oriented grains and principally low angle grain boundaries. The atomic ordering allows for high current densities, e.g. J_{C} greater than or equal to 100,000 amps per cm².

Each SC piece 403, 404 may comprise a metal foil tape that is from 10/1000 to 1/1000 of an inch thick. Each SC piece 403, 404 may be composed of nickel and/or a nickel alloy, and have a predetermined atomic ordering which promotes growth of the HTS material. The tape may also comprise nickel, silver, palladium, platinum, copper, aluminum, iron, tungsten, tantalum, vanadium, chromium, tin, zinc, molybdenum, and titanium. Such a tape has been described by Oak Ridge National Laboratories. The nickel portion supports the HTS layer, and thus should be ductile or flexible, as well as strong.

Joiner 400 comprises lower portion 401 and removable upper portion 402. Upper portion 402 may be a lid on lower portion 401. Upper portion 402 may be removable, thereby allowing a user to access the interior of joiner 400, e.g. to align SC pieces 403, 404 for joining. Upper portion 402 and lower portion 401, when connected to each other, are sealed by seal 419. The seal may prevent leakage of the exterior atmosphere into joiner 400, and prevents leakage of the atmosphere of joiner 400 into the exterior atmosphere.

Joiner 400 comprises at least one support 405, preferably composed of stainless steel. Other materials may include quartz, gold, platinum, aluminum oxide, LaAlO₃, SrTiO₃, and/or other metal oxide materials. In many embodiments, support 405 should be polished smooth, so as not to snag or kink the tape, which may result in damage to the atomic ordering of the substrate and result in reduced quality HTS film. Also, in various embodiments, the support should only be as large as necessary to prevent sag—this will minimize contact with the tape and help to prevent contamination. Support 405 may include a heater to supplement heat provided by heating element 406, e.g., a lamp. This prevents support 405 from acting as a heat sink. The sides of joiner 400 may comprise stainless steel or may comprise some other non-reactive material such as quartz, gold, platinum, aluminum oxide, LaAlO₃, SrTiO₃, and/or other metal oxide materials.

Joiner 400 includes shower head (or distribution head) 407 and adjacent heating source or lamp 408. Lamp 408 heats the tape to a desired temperature to allow for the deposition of materials. Lamp 408 also provides ultraviolet and visible light, which significantly enhance the growth rate, i.e., increase the speed of growth through enhanced surface diffusion of the reacting species, which in turn may allow for rapid growth of thick layers, and faster tape speeds and/or smaller reactors. Lamp 408, in this example, includes a reflector to direct the light onto reaction area 421, which is the area immediately beneath shower-head 407. This may reduce heat flux to the chamber walls. Lamp 408, in at least one embodiment, is a quartz halogen lamp that includes a plurality of light bulbs that surround shower head 407. Note that other ultraviolet/visible (UV/V) light sources may be used, for example xenon discharge, mercury vapor, or excimer laser light. Shower-head 407 provides a laminar flow of the precursors or reactant vapors mixed with a carrier gas to reaction area 421. Shower-head 407 is preferably made from stainless steel, but may also be another non-reacting material such as quartz, gold, platinum, aluminum oxide, LaAlO₃, SrTiO₃, and/or other metal oxide materials.

Joiner 400 includes one or more gas ports, such as gas port 409, to allow the introduction of at least one gaseous specie into joiner 400 to provide an atmosphere suitable for the joining process. The gas may be an inert gas, e.g. helium or argon, or may be a gas that would stabilize or enhance the joining process. For example, during the one step of the joining process, port 409 may provide oxygen or other oxidizing gases such as O₃, N₂O, etc. During another step, port 409 may provide hydrogen or other reducing gases, e.g. NH₃.

One or more vacuum port(s) 410 provide an outlet for the materials that are to be used in joiner 400. In other words, material flows in from shower head 407 and/or gas port 409 and then out through port 410.

Note that as shown in FIG. 4, the two pieces of SC material 403, 404 have a length larger than joiner 400. Thus, joiner 400 comprises two or more isolation sections 411, 412, which isolate the portions of SC pieces 403, 404 that are to be joined from the remainder of pieces 403, 404. Isolation sections 411, 412 allow the portions of SC pieces 403, 404 that are to be joined to be exposed to the proper environment (e.g. temperature, pressure, and gases) for joining. Each isolation section 411, 412 may comprise one or more slits, a gas source, and a vacuum source. In this example, the slits operate to minimize the passage of gases and other materials from joiner 400 to the exterior atmosphere, and vice-versa. Slit 417 may be formed from hermetic seal 420. Seal 420 may be opened to allow for an SC piece to be moved into position in joiner 400, and then be closed to seal joiner 400 from the external environment.

Each isolation section 411, 412 has a vacuum port, such as port 416, that pulls in any materials or gases leaking into the isolation section from either slit. Port 416 may be operated at a pressure that is either higher or lower than port 410. Each isolation section 411, 412 may include at least one port 415 to allow for the introduction of at least one gaseous specie into the isolation section. The gas may be an inert gas, e.g. helium or argon, or may be a gas that would stabilize or enhance the joining process. For example, during the one step of the joining process, port 415 may provide oxygen or other oxidizing gases such as O₃, N₂O, etc. During another step, port 415 may provide hydrogen or other reducing gases, e.g. NH₃. In this example, any introduced gaseous materials may be removed by vacuum port 416.

Joiner 400 also includes ion gun 413. Ion gun 413 dispenses one or more types of ions toward reaction area 421. For example, ion gun 413 may be used to impart argon ions (Ar+) onto reaction area 421 to clean the surfaces of the two pieces being joined. The ion bombardment ensures that the surfaces are free of contaminants, smooth after the welding process, and have good atomic order and no chemical contamination.

Jointer 400 also includes quality control port 414. Port 414 operates to allow viewing of the tape pieces during the joining process, and/or permit access for testing the quality of the joined tape.

Joiner 400 may also have electrodes 422 and 423, to be used in the welding of the substrates of the two tape pieces. Note that the electrodes may be separate from joiner 400.

Various portions of joiner 400 may comprise cooling jackets or cooling pipes, e.g. the sides of the joiner, the isolation portions, the lamp housing or reflector. Different coolants may be used in the jackets, e.g. water, oil, glycol, etc. The cooling jacket(s) or pipes may operate not to only reduce the reaction chamber external temperature to a safe range, but also to reduce unwanted buildup of deposition materials on the walls by reducing the wall temperature to a point where chemical reaction of species does not occur.

Note that various sensors (not shown) may be placed throughout the system to provide data regarding the operation of joiner 400, e.g. environmental data, temperature, etc.

Further note that after joining, the joined tape (comprising SC pieces 403, 404) may be removed by pulling the tape through the joiner. For long tape lengths this may be impracticable, thus joiner 400 would have to be separated such that top portion 490 of joiner 400 would be separated from bottom portion 491. Alternatively, a side portion (not shown, e.g. out of the page) may be removed to allow for the tape (of joiner 400) to be moved sideways (orthogonal to the direction of the tape) to allow tape to be removed from joiner 400.

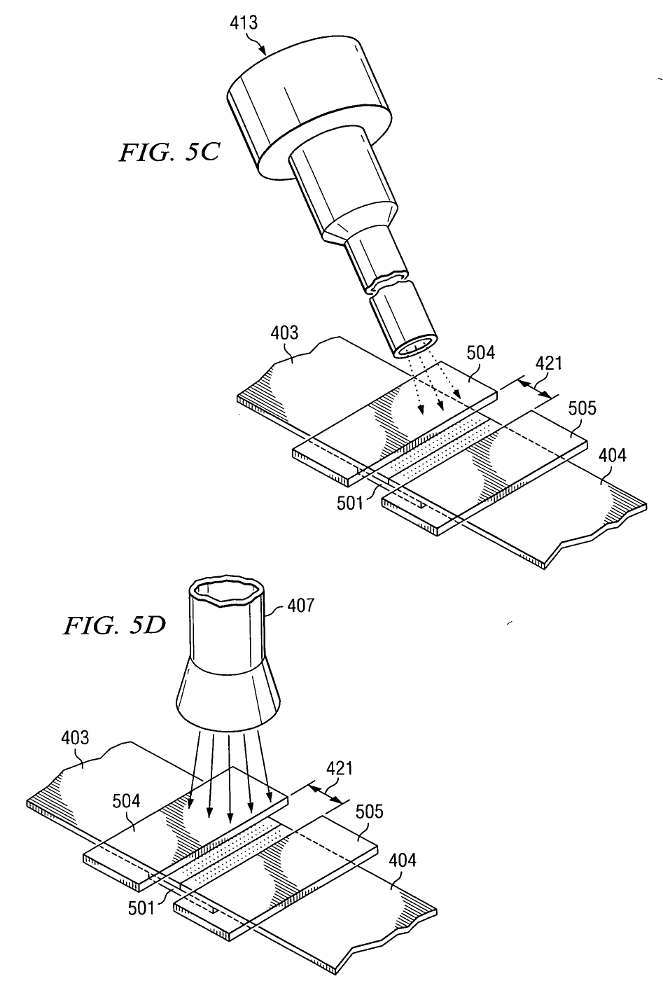

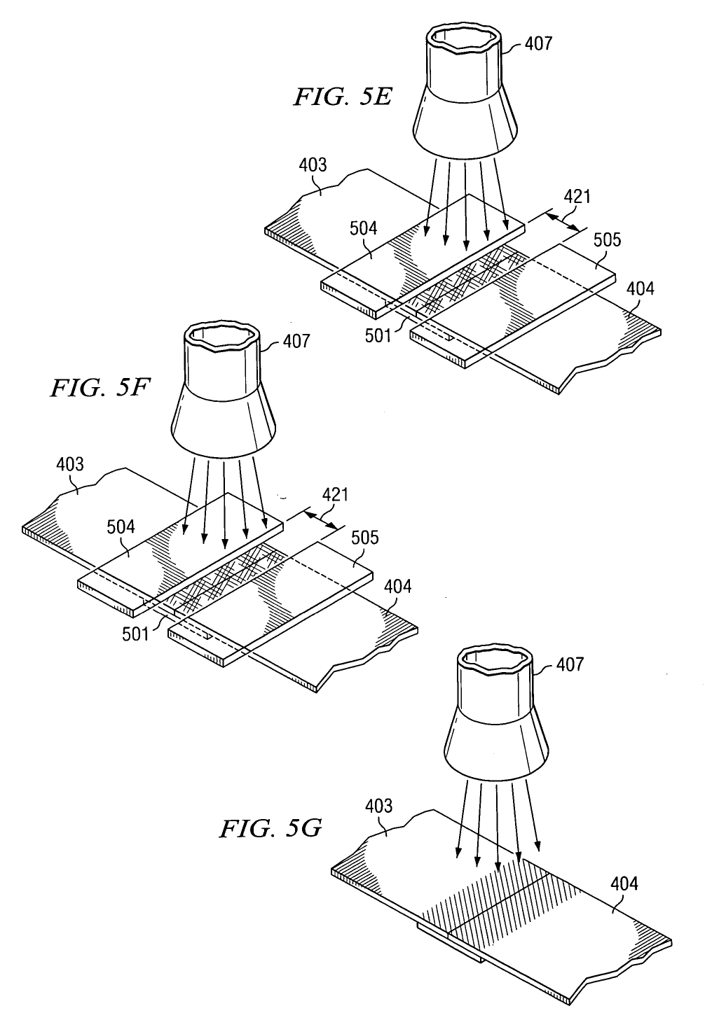

FIGS. 5A-5G depict exemplary processes for using joiner 400 of FIG. 4 to join two pieces of SC material. Prior to insertion, the two pieces prefereably have good, clean, sheared edges for joining. Also, each piece should preferably be cleaned by chemical etching, mechanical polishing, or with ion bombardment (e.g., by ion gun 413) to remove the superconductor layer along with any buffer layers (if any) within this joining region to leave a bare substrate.

In FIG. 5A, the two pieces of SC material 403, 404 are inserted into joiner 400. Patch 501 is used to provide support for the joint that will be formed to connect pieces 403, 404. Patch 501, in this example, comprises a material that is similar to the substrate material of SC pieces 403, 404. For example, if the substrate of SC pieces 403, 404 comprises nickel, then patch 501 may comprise nickel, nickel-tungsten, or nickel-molybdenum. Patch 501 should be sized so as to extend under each piece 403, 404 when two pieces 403, 404 are in contact with each other.

In FIG. 5B, the two pieces of tape 403, 404, as well as patch 501 are placed in a holder which comprises two clamps 502 and 503. Pieces 403, 404 and patch 501 are aligned with each other, and then joined mechanically via clamps 502, 503. Pieces 403, 404 are then butt-welded and patch 501 is welded to pieces 403 and 404, for example via electrodes 422, 423. Current is passed through clamps 502, 503 to weld the substrates of pieces 403, 404 together and/or weld patch 501 to each of pieces 403, 404.

In FIG. 5C, the welded tape is then subjected to ion bombardment with ion gun 413 to clean the weld region, remove any residual buffer and/or superconductor material from the weld region, and/or to prepare the welded tape for substrate-material deposition. Masks 504, 505 are used to prevent bombardment on other regions of the tape. After cleaning, masks 504, 505 may be opened slightly, and then the tape is subjected to further bombardment. This may allow for a protective cover to be removed from the tape, thereby exposing the superconductor material.

FIG. 7 depicts tape piece 404, after cleaning which exposes substrate 701, and the removal of protective cover 702 which exposes superconductor layer 703 (which is on top of buffer layer 704). Later in the joining process, both buffer and superconductor material will be deposited in the reaction area and on to the exposed superconductor material of the two tape pieces. A typical environment for cleaning may be argon and/or argon ion (Ar+) at a moderate vacuum (e.g. 5-15 mTorr), at a temperature of 30-200° C. In this example, the gas for the atmosphere is provided at gas port 409, the ions are provided by ion gun 413, the heat and/or light is provided by lamps or other heaters 408, 406, and the vacuum is provided by vacuum port 410.

In FIG. 5D, a layer of substrate material is deposited onto the tape substrate in the reaction area. Deposition processes may include physical vapor deposition and/or chemical vapor deposition processes. The preferred embodiment is metal organic chemical vapor deposition (MOCVD). Masks 504, 505 protect tape pieces 403, 404 (including the superconductor material exposed in FIG. 5C) and allow only the cleaned substrate to be exposed for deposition. For example, if the substrate comprises nickel, then nickel, nickel-tungsten, or nickel-molybdenum may be deposited on the clean and atomically ordered substrate section. This layer provides an atomically ordered area (e.g. order 100) overlapping the joint area that will promote the growth of the buffer layer(s) (if any) and the superconductor layer. The metal layer may be in the order of 0.5 microns to 10 microns thick. This metal layer will minimize the effects of atomic misalignment at the joint of the two pieces. A typical environment for this step under MOCVD may be argon at a moderate vacuum (e.g. 1-10 Torr), at a temperature of 400-700° C. In this example, the gas for the atmosphere is provided at gas port 409, the substrate material organometallic precursor is provided by shower head 407, the energy for the MOCVD reaction is provided by lamps or other heaters 408, 406, and the vacuum is provided by vacuum port 410.

In FIG. 5E, a layer of buffer material may be deposited onto the layer of substrate material deposited in FIG. 5D. Deposition processes may include physical vapor deposition and/or chemical vapor deposition processes. The preferred embodiment is metal organic chemical vapor deposition (MOCVD). The buffer material, if needed, would provide a diffusion barrier for formation of the superconductor layer. Some examples of buffer materials are cerium oxide (CeO₂ or CEO), yittria stabilized zirconia (Y₂O₃—ZrO₂ or YSZ), Gd₂O₃, Eu₂O₃, Yb₂O₃, RuO₂, La₁₋ₓ, SrₓCoO₃, MgO, SiN, BaCeO₂, NiO, Sr₂O₃, SrTiO₃, and Ba₁₋ₓSrₓTiO₃. Other buffer materials may be used. A typical environment for this step may be argon, oxygen, and/or hydrogen at a moderate vacuum (e.g. 1-10 Torr), at a temperature of 450-850° C. Different types of buffer material may require different atmospheric conditions. FIG. 5E may be repeated if multiple buffer layers are needed. The process depicted in FIG. 5E may be omitted if the superconductor material will form on the substrate material without any buffer. In this example, the gas for the atmosphere is provided at gas port 409, the buffer material organometallic precursor is provided by shower head 407, the energy for the MOCVD reaction is provided by lamps or other heaters 408, 406, and the vacuum is provided by vacuum port 410.

In FIG. 5F a layer of superconductor material may be deposited onto the buffer layer(s) formed in FIG. 5E or onto the deposited substrate material of FIG. 5D. Deposition processes may include physical vapor deposition and/or chemical vapor deposition processes. The preferred embodiment is metal organic chemical vapor deposition (MOCVD). In any event, masks 504, 505 are opened so that the superconductor material may be deposited on the exposed superconductor material from FIG. 5C. This connects the superconductor layer of piece 403 with the superconductor layer of piece 404.

Some examples of superconductor material are YBa₂Cu₃O₇₋ₓ, YBCO, NdBa₂Cu₃O₇₋ₓ, LaBa₂Cu₃O₇₋ₓ, Bi₂Sr₂Ca₂Cu₃O_{y}, Pb₂₋ₓBiₓSr₂Ca₂Cu₃O_{y}, Bi₂Sr₂CaCu₂O_{z}, Tl₂Ba₂CaCu₂Oₓ, Tl₂Ba₂Ca₂Cu₃O_{y}, TlBa₂Ca₂Cu₃O_{z}, Tl₁₋ₓBiₓSr_{2-y}Ba_{y}Ca₂Cu₄O_{z}, TlBa₂CaCu₂O_{z}, HgBa₂CaCu₂O_{y}, HgBa₂Ca₂Cu₃O_{y}, MgB₂, copper oxides, rare earth metal oxides, and other superconductors. A typical environment for this step may be argon, oxygen, and/or nitrous oxide at a moderate vacuum (e.g. 1-10 Torr), at a temperature of 700-900° C. Different types of superconductor material would require different atmospheric conditions. In tis example, the gas for the atmosphere is provided at gas port 409, the different organometallic precursors for the superconductor material are provided in vapor form by a number of vaporization techniques to shower head 407, the energy for the MOCVD reaction is provided by lamps or other heaters 408, 406, and the vacuum is provided by vacuum port 410.

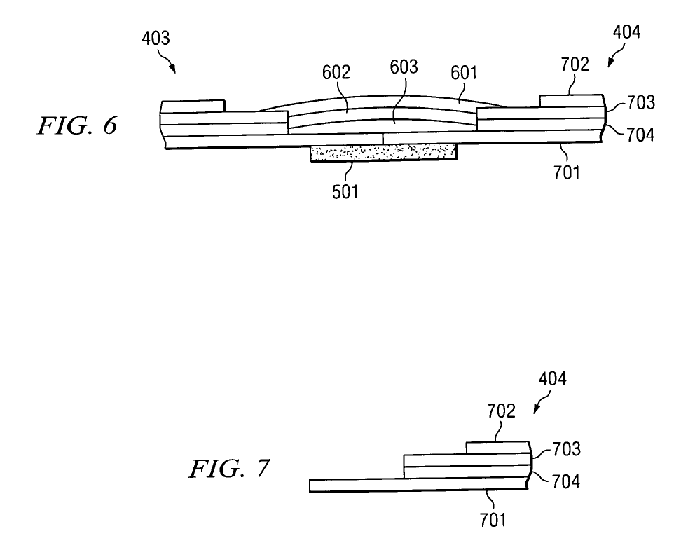

FIG. 6 depicts an example of a joined superconductor tape formed from two pieces 403, 404. The joined superconductor tape includes substrate patch 501, substrate material layer 603, buffer layer 602, and superconductor layer 601.

In FIG. 5G a protective layer of silver is deposited onto the superconductor layer. No mask is need for this step.

Joiner 400 may be used to connect two pieces of SC material that are used in, e.g., the transporting of current, the distribution of power, electric motors, electric generators, in a transformer, fault current limiters, superconducting magnetic energy storage (SMES) systems, and a variety of magnets (including, but not limited to, MRI systems, magnetic levitation transport systems, particle accelerators, and magnetohydrodynamic power systems).

The joiner may be used to connect two pieces of SC material selected from the group of SC material including, but not limited to YBa₂Cu₃O₇₋ₓ, YBCO, NdBa₂Cu₃O₇₋ₓ, LaBa₂Cu₃O₇₋ₓ, Bi₂Sr₂Ca₂Cu₃O_{y}, Pb₂₋ₓBiₓSr₂Ca₂Cu₃O_{y}, Bi₂Sr₂CaCu₂O_{z}, Tl₂Ba₂CaCu₂Oₓ, Tl₂Ba₂Ca₂Cu₃O_{y}, TlBa₂Ca₂Cu₃O_{y}, Tl₁₋ₓBiₓSr_{2-y}Ba_{y}Ca₂Cu₄O_{z}, TlBa₂Ca₁Cu₂O_{z}, HgBa₂CaCu₂O_{y}, HgBa₂Ca₂Cu₃O_{y}, MgB₂, copper oxides, rare earth metal oxides, and other high temperature superconductors. In the process of joining the SC pieces the joiner may also use different buffer materials, including but not limited to CeO₂ (or CEO), Y₂O₃—ZrO₂ (or YSZ), Gd₂O₃, Eu₂O₃, Yb₂O₃, RuO₂, La₁₋ₓSrₓCoO₃, MgO, SiN, BaCeO₂, NiO, Sr₂O₃, SrTiO₃, and Ba₁₋ₓSrₓTiO₃.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A portable system for joining two superconductor pieces comprising:
a support arranged for holding the two superconductor pieces adjacent to each other in a reaction area;
a distribution head positioned to deposit at least one material onto the reaction area used in joining the two superconductor pieces;
an ion gun positioned to bombard the reaction area with ions;
a gas port arranged for providing at least one gas to the system; and
a vacuum port arranged for establishing a desired atmospheric pressure in the system.

2. The portable system of claim 1, further comprising:
at least one seal arranged for sealing the two superconductor pieces in the system.

3. The system of claim 1 wherein the system is portable and includes an upper portion and a lower portion that may be separated.

4. The system of claim 1 further including a clamp system positioned to align the two superconductor pieces with each other and with a patch and to pass a current through the patch and substrate layers associated with each piece.

5. The system of claim 1 further comprising at least one isolation chamber with an hermetic seal positioned to prevent mixing of an exterior atmosphere with an atmosphere present at the reaction area.

6. The system of claim 5 wherein the isolation chamber comprises an atmosphere of an inert gas.

7. The system of claim 1 further comprising a lamp positioned to direct light on to the reaction area.

8. A method for joining a first and a second superconductor piece in a single tape comprising:
aligning the first piece and the second piece proximate to each other;
welding a substrate of the first piece to a substrate of the second piece at a reaction area to form the single tape;
depositing a layer of substrate material on one side of the reaction area of the tape; and
depositing a layer of superconductor material on the one side of the reaction area of the tape, wherein the deposited layer of superconductor material adjoins a superconductor layer of the first piece and adjoins a superconductor layer of the second piece.

9. The method of claim 8, further comprising:
cleaning the end of each piece that is to be joined to the other piece to expose the substrate of each piece.

10. The method of claim 8, further comprising:
depositing at least one buffer layer onto the deposited layer of substrate material;
wherein the superconductor layer is deposited onto the at least one buffer layer.

11. The method of claim 8 further comprising:
applying a protective layer of silver to the superconductor layer.

12. The method of claim 8 wherein the aligning, the welding, and each of the depositing steps are performed with a portable joiner.

13. The method of claim 8 further comprising:
maintaining a desired gas pressure at the reaction area.

14. A portable system for joining two superconductor pieces comprising:
means for holding the two superconductor pieces adjacent to each other in a reaction area;
means for depositing at least one material onto the reaction area used in joining the two superconductor pieces;
means for bombarding the reaction area with ions;
means for providing at least one gas to the system; and
means for establishing a desired atmospheric pressure in the system.

15. The system of claim 14 further comprising:
means for isolating an external atmosphere from an atmosphere associated with the reaction area.

16. The system of claim 14 further comprising:
an upper portion and a lower portion that are separable to allow an ingress and egress of the two superconductor pieces.

17. The system of claim 14 further comprising:
means for providing gases to the reaction area; and
means for maintaining an appropriate pressure at the reaction area.

18. A method for splicing a first and a second superconductor wire, wherein each wire includes a substrate tape, a superconductor layer, and a buffer layer between the substrate tape and the superconductor layer, comprising:
removing a portion of the superconductor layer and the buffer layer from a joining region of each wire;
aligning the joining regions of each wire with each other and with a patch;
welding the patch and the joining regions;
cleaning the welded joining regions with ion bombardment;
depositing an atomically ordered layer of substrate material onto the joining regions;
depositing a buffer layer on the atomically ordered layer of substrate material;
depositing a layer of superconductor material on the buffer layer such that the layer of superconductor material contacts the superconductor layers on each of the superconductor wires; and;
depositing a protective layer on top of the layer of superconductor material.

19. The method of claim 18 wherein one or more of the depositing steps are performed through a metal organic chemical vapor deposition (MOCVD).

20. The method of claim 18 wherein the method is performed using a portable joiner that includes an upper portion and a lower portion that are separable.

21. The method of claim 18 further comprising:
providing gases to the joining regions; and
maintaining an appropriate gas pressure at the joining regions.

22. A system for splicing a first and a second superconductor wire, wherein each wire includes a substrate tape, comprising:
a reaction chamber including an upper portion and a lower portion, wherein the upper and lower portions are separable;
a clamp system to align and weld the substrate tapes of each superconductor wire;
an ion gun positioned to direct ions at a reaction area in the reaction chamber;
at least two gas ports arranged to maintain a proper atmosphere in the reaction chamber;
a deposition head arranged to supply reactant to the reaction area; and
a hermetic seal to isolate the proper atmosphere in the reaction chamber from an external atmosphere.
